(19) United States
(12) Patent Application Publication
(10) Pub. No.: US 2016/0028272 A1
(43) Pub. Date: Jan. 28, 2016

(54) HOUSING HAVING A SOLAR PANEL AND COMPONENTS CAPABLE OF REPLENISHING A MOBILE PHONE BATTERY

(71) Applicant: Edward James Dukes, Sarasota, FL (US)

(72) Inventor: Edward James Dukes, Sarasota, FL (US)

(73) Assignee: INNOVATIVE SOLAR INDUSTRIES INC., Sarasota, FL (US)

(21) Appl. No.: 14/339,574

(22) Filed: Jul. 24, 2014

(51) Int. Cl. H02J 7/35; H05K 5/02; H05K 5/00

(52) U.S. Cl. CPC H02J 7/355; H05K 5/0017; H05K 5/0086; H05K 5/0217; H02J 7/007

(57) ABSTRACT

A mobile phone having an integrated solar powered charging system includes a housing with a solar panel, a regulating circuit, and a cord. The solar panel is connected to the regulating circuit with an electrically conductive element. An electrical current generated by the solar panel is transferred through a conductor to the regulating circuit. When the battery cover is installed onto the mobile phone, the regulating circuit contacts and charges the mobile phone battery. The solar powered charging system can be incorporated into an adjustable charging dock for a tablet or a mobile phone having a housing with an integrally formed solar panel connected to a regulating circuit that is electrically connected to the mounting surface of the charging dock. A mobile device is connected to the mounting surface of the charging dock to receive a charge.

### BACKGROUND OF THE INVENTION

1. Field of the Invention

This invention relates, generally, to a solar powered cell phone battery charger.

2. Background Art

Cell phones use a battery to power the cell phone device. The battery is connected to an electrical outlet or to a docking station that is connected to an electrical outlet for the recharging of the battery. The use of household Alternating Current (AC) can be costly and may not be available in certain areas to be used as a power source to recharge a battery. Thus, there is a need for a cell phone to be configured to receive energy through solar power to maintain battery power.

Prior art solar charging devices include a separate charging device having a solar panel, an external battery, and a port which receives a cable to connect to a cell phone. There is a need for an integral solar powered charging system that is adapted to communicate with a cell phone, a cell phone case, or to a cell phone charging dock.

Currently, large solar panels having a size of approximately 6 inches by 10 inches have a USB cable capable of connecting to and charging a mobile phone. It is more desirable to be able to maintain battery power with a solar power housing attached to the mobile phone. The problem with maintaining a constant battery charge is determining how to configure the solar panel to be portable and how to configure the solar panel to communicate with a mobile device.

However, in view of the prior art considered as a whole at the time the present invention was made, it was not obvious to those of ordinary skill in the pertinent art how the identified needs could be fulfilled.

### SUMMARY OF THE INVENTION

The long-standing but heretofore unfulfilled need for a mobile phone having an integrated solar powered charging system having a housing with a solar panel, a regulating circuit, and a cord which also includes improvements that overcome the limitations of prior art solar powered battery chargers is now met by a new, useful, and non-obvious invention.

In a preferred embodiment, the novel mobile phone having an integrated solar powered charging system has a portion of the mobile phone containing an integral solar panel connected to a regulating circuit. It is within the scope of this invention for all embodiments of this invention to encompass the solar panel being connected to including, but not limited to, a regulating circuit or a diode. The portion of the mobile phone includes, but is not limited to, a battery cover. A solar panel is connected to a regulating circuit with an electrically conductive element including, but not limited to, a circuit board, an electrically conductive wire, a conductor, or wireless communication. An electrical current generated by the solar panel is transferred through a conductor to the regulating circuit. When the battery cover is installed onto the mobile phone, the regulating circuit contacts the mobile phone battery. It is within the scope of this invention for power to be wirelessly transmitted from a solar panel to a mobile device containing a battery. A preferred embodiment of wireless charging of this novel invention is inductive charging. An alternate embodiment includes a solar panel connected to a mobile device's regulating circuit that maintains the mobile device battery charge level.

In an alternate embodiment, the novel solar powered charging device is integrated into a mobile phone case. The mobile phone case is a housing containing a solar panel, a regulating circuit, and a cord. It is within the scope of this invention for the mobile phone case to including, but not be limited to, a case with a foldable flap, a water proof case, a mobile device container, or any case that secures a mobile phone. It is also envisioned that the case housing have a plurality of detachable barrier portions that interconnect to provide a protective barrier for including, but not limited to, the solar panel or the mobile device. The solar panel has a surface that is adapted to be exposed to sunlight. The solar panel is connected to a regulating circuit. An electrical current generated by the solar panel is transferred through a conductor to the regulating circuit. A cord has a primary end connected to the regulating circuit and an opposite secondary end that is adapted to be received by including, but not limited to, a mobile phone port.

The mobile phone case is adapted to closely contour a mobile phone. The cord can be contained by a recess in the mobile phone case to secure the cord in place. It is also within the scope of this invention for the novel solar powered charging system to be integrated into a tablet case, a laptop case, or a charging dock. In a preferred embodiment, the housing can have a thermal radiant barrier. The thermal radiant barrier is capable of slowing the transfer of heat from the sun to the device being powered by solar power so that the device does not become damaged from being overheated. The housing is of a material including, but not limited to, rubber, plastic, or metal. It is also within the scope of this invention for a portion of the mobile phone case to contact a portion of a mobile phone.

In another embodiment, the novel solar powered charging system can be connected to existing mobile phones. A housing having a solar panel, a regulating circuit, an attaching element, and a cord can be connected to a surface of including, but not limited to, a mobile phone, a mobile phone case, a tablet, a tablet case, or a laptop. The cord connects the regulating circuit to the mobile device. An attaching element includes, but is not limited to, a hook and loop attachment, adhesive, tape, double sided tape, magnets, or a snap. It is within the scope of this invention to have a wireless regulating circuit without the need of a cord to connect the regulating circuit to a mobile device. It is envisioned that the electrical conductor encompass including, but not limited to, a cord, a tether, an internal ribbon cable, or wireless technology.

In another embodiment, the novel solar powered charging system can be connected to an adjustable charging dock for including, but not limited to, a tablet or a mobile phone. A housing is adapted to connect to a docking station. The housing has a solar panel integrally formed within the housing. The solar panel is connected to a regulating circuit. The regulating circuit is electrically connected to the mounting surface of the charging dock. A mobile device is connected to the mounting surface of the charging dock to receive a charge. It is envisioned that the novel solar powered charging dock includes speakers and an adjustable hinged base to change the pitch of the mobile device electronic display. It is within the scope of this invention for the solar panel housing to be connected to a surface of the charging dock with an attaching element. It is also within the scope of this invention for the docking station to be the housing having a solar panel integrally formed within the housing.

The electrical charging dock for a wireless device in bidirectional communication with a communication system includes a supporting structure having a solar panel integrally formed within the supporting structure. The supporting structure is in electrical communication with a wireless device. An output circuit is in electrical communication with a solar panel generating an electrical current to a regulating circuit. The regulating circuit is in electrical communication with at least one electrical conductor having a primary end in electrical communication with the regulating circuit. At least one electrical conductor having a secondary end in electrical communication with the wireless device.

The electrical charging dock for a wireless device in bidirectional communication with a communication system can have a supporting structure pivotally connected (not shown) to a receiving structure. The receiving structure is configured to support a wireless device. It is a preferred embodiment of the present invention that the receiving structure has an inductive charging primary coil adapted to come into contact with an inductive charging secondary coil (not shown) of a wireless device. It is also within the scope of this invention for the electrical charging dock to have a digital display and memory capacity.

The electrical charging dock for a wireless device in bidirectional communication with a communication system can have a dock connected to at least one speaker. The electrical charging dock also includes an integral battery storage capacity. It is also envisioned that this invention includes a separate solar panel for a user to place in a location of direct sunlight to charge a device that is not being exposed to direct sunlight. The solar panel has a surface that is adapted to be exposed to sunlight. The solar panel is connected to a regulating circuit. An electrical current generated by the solar panel is transferred through a conductor to the regulating circuit. A cord has a primary end connected to the regulating circuit and an opposite secondary end that is adapted to be received by including, but not limited to, a mobile phone port or an electrical charging dock. For example, the solar panel can be connected to a roof. The electrical conductor connected to the regulating circuit of the solar panel can be brought into an area of limited or no sunlight where an end of the regulating circuit can connect to an electronic device.

It is therefore an important object of the present invention to provide a housing having a solar panel, a regulating circuit, a cord, and an attaching element to connect to including, but not limited to, a mobile phone, a tablet, a tablet case, or a mobile phone case.

Another important object of the present invention is to provide an integral housing having a solar panel and a regulating circuit adapted to be built into to an existing mobile phone, tablet, or docking system.

### BRIEF DESCRIPTION OF THE DRAWINGS

For a fuller understanding of the nature and objects of the invention, reference should be made to the following detailed description, taken in connection with the accompanying drawings, in which:

FIG. 1 is a perspective front view of the novel integral solar powered battery cover housing;

FIG. 2 is a perspective side view of the novel integral solar powered battery cover housing;

FIG. 3 is a perspective front view of the novel integral solar powered mobile phone case housing;

FIG. 4 is an exploded view of the novel integral solar powered mobile phone case housing;

FIG. 5 is a perspective side view of the novel integral solar powered mobile phone case housing;

FIG. 6 is a perspective side view of the novel solar powered housing having an attaching element; and,

FIG. 7 is a perspective front view of the novel solar powered housing having an attaching element.

FIG. 8 is a perspective view of the novel charging dock.

FIG. 9 is an exploded view of the novel charging dock.

FIG. 10 is a front perspective view of the novel charging dock having a digital display.

FIG. 11 is a rear perspective view of the novel charging dock having a solar panel.

### DETAILED DESCRIPTION OF THE PREFERRED EMBODIMENT

In the following detailed description of the preferred embodiments, reference is made to the accompanying drawings, which form a part hereof, and within which are shown by way of illustration specific embodiments by which the invention may be practiced. It is to be understood that other embodiments may be utilized and structural changes may be made without departing from the scope of the invention.

In a preferred embodiment the novel wireless device in bidirectional communication with a communication system has housing 2. A wireless device in bidirectional communication with a communication system includes, but is not limited to, a phone, a computer, or a tablet having internet or phone. A communication system is any way of connecting a primary device to a secondary device including, but not limited to, a phone network or the internet. Housing 2 is adapted to connect to a portion of wireless device 1. Housing 2 has solar panel 3 integrally formed within housing 2. Output circuit 6 connects solar panel 3 generating an electrical current to regulating circuit 5. Output circuit 6 is any electrically conductive element including, but not limited to, a circuit board or a wire. Regulating circuitry 5 is electrically connected to battery 4. Battery 4 is electrically connected to wireless device 1.

In an alternate embodiment, the novel housing encasing a wireless device in bidirectional communication with a communication system has housing 7. Housing 7 has solar panel 3 integrally formed within housing 7. Output circuit 6 connects solar panel 3 generating an electrical current to regulating circuit 5. Regulating circuit 5 is connected to at least one electrical conductor 8. Electrical conductor 8 has primary end 12 connected to a portion of regulating circuit 5 and secondary end 13 connected to wireless device 1 port 9.

In another embodiment, the novel housing connected to a wireless device in bidirectional communication with a communication system has housing 10 connected to solar panel 3. Output circuit 6 connects solar panel 3 generating an electrical current to regulating circuit 5. Regulating circuit 5 is connected to at least one electrical conductor 8. Electrical conductor 8 has primary end 12 connected to a portion of regulating circuit 5 and secondary end 13 connected to wireless device 1 port 9. Attaching element 11 is connected to a surface of housing 10. Housing 10 is configured to connect to wireless device 1.

In another embodiment the novel memory device having an electronic display (not shown) has housing 2. A memory device having an electronic display is anything that electronically displays information including, but not limited to, a nook or a tablet without internet or phone, an LCD screen, a plasma screen, or an LED screen. Housing 2 is adapted to connect to a portion of the memory device having an electronic display. Housing 2 has solar panel 3 integrally formed within housing 2. An output circuit connects solar panel 3 generating an electrical current to regulating circuit 5. An output circuit is any electrically conductive element including, but not limited to, a circuit board or a wire 6. Regulating circuitry 5 is electrically connected to battery 4. Battery 4 is electrically connected to the memory device having an electronic display.

In an alternate embodiment, the novel housing encasing a memory device having an electronic display (not shown) has housing 7. Housing 7 has solar panel 3 integrally formed within housing 7. An output circuit 6 connects solar panel 3 generating an electrical current to regulating circuit 5. Regulating circuit 5 is connected to at least one electrical conductor 8. Electrical conductor 8 has primary end 12 connected to a portion of regulating circuit 5 and secondary end 13 connected to the port of a memory device having an electronic display.

In yet another embodiment, the novel housing connected to a memory device having an electronic display (not shown) has housing 10 connected to solar panel 3. Output circuit 6 connects solar panel 3 generating an electrical current to regulating circuit 5. Regulating circuit 5 is connected to at least one electrical conductor 8. Electrical conductor 8 has primary end 12 connected to a portion of regulating circuit 5 and secondary end 13 connected to the port of a memory device having an electronic display. Attaching element 11 is connected to a surface of housing 10. Housing 10 is configured to connect to the memory device having an electronic display.

In another embodiment, the electrical charging dock includes supporting structure 15 having solar panel 3 integrally formed within supporting structure 15. Supporting structure 15 is in electrical communication with wireless device 1. Output circuit 6 is in electrical communication with solar panel 3 generating an electrical current to regulating circuit 5. Although not a preferred embodiment, it is within the scope of this invention for regulating circuit 5 to be in electrical communication with at least one electrical conductor 8 having primary end 12 in electrical communication with regulating circuit 5. At least one electrical conductor 8 to have secondary end 13 in electrical communication with wireless device 1. The preferred embodiment for supporting structure 15 being in electrical communication with wireless device 1 is inductive charging.

### Construction of the Novel Solar Powered Mobile Device Charger

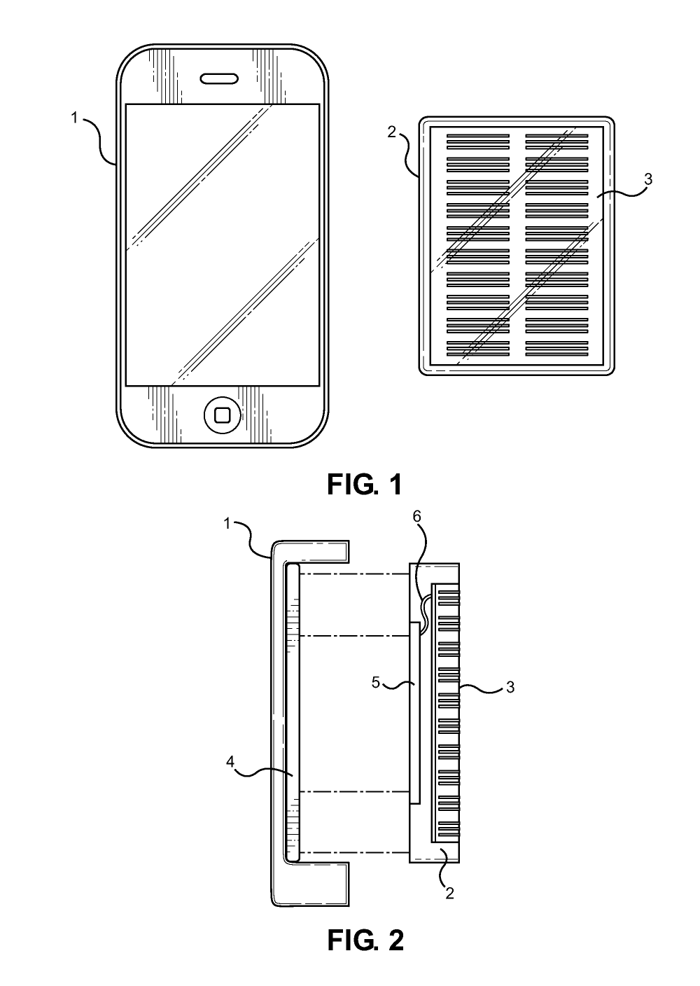

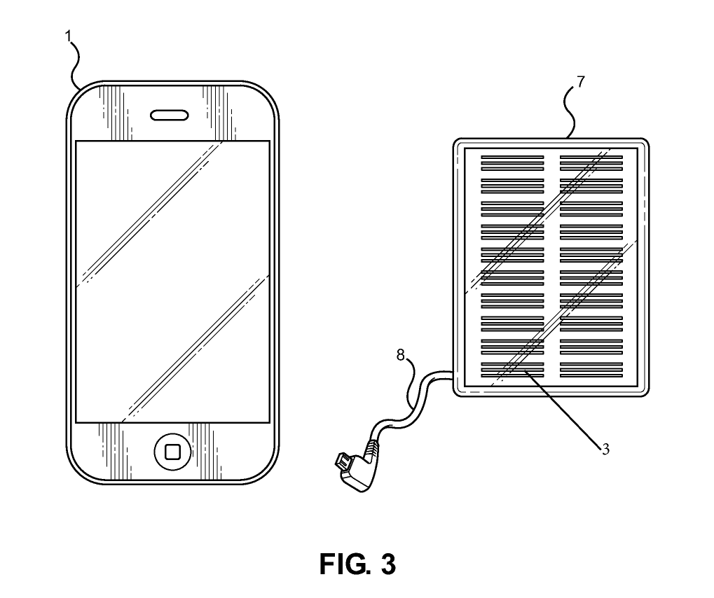

It will now be seen, referring to FIGS. 1 and 2, wireless device 1 has novel housing 2. Housing 2 has integral solar panel 3 located thereon housing 2. FIG. 2 illustrates conductive wire 6 connecting solar panel 3 to regulating circuit 5. Regulating circuit 5 is electrically connected to battery 4. Battery 4 is electrically connected to wireless device 1.

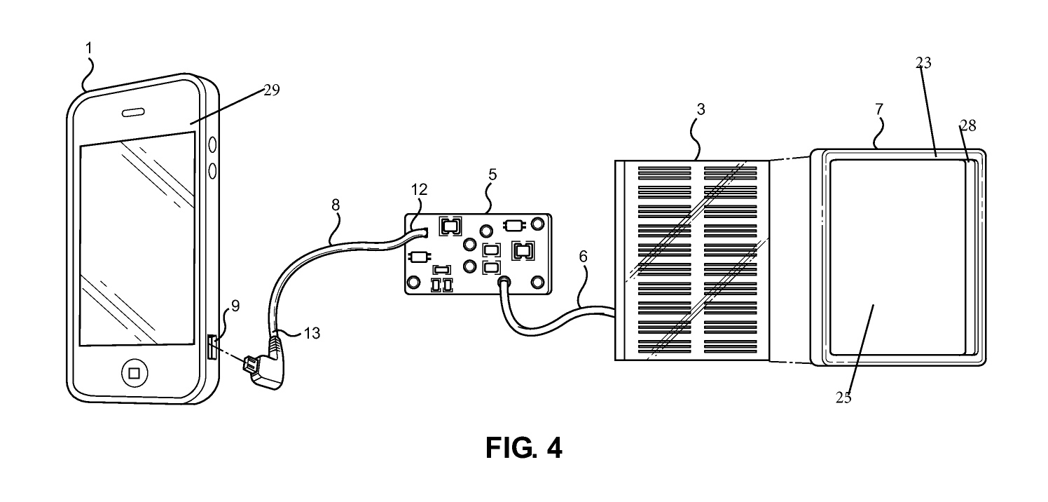

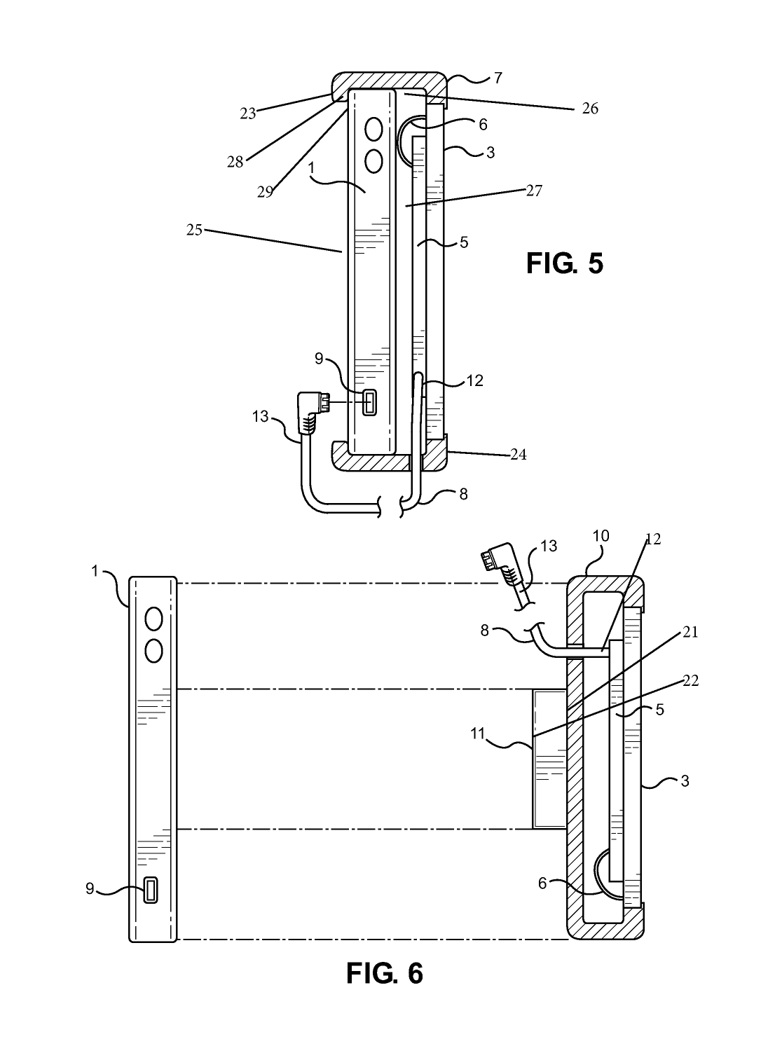

FIG. 5 shows housing 7 encasing wireless device 1. FIGS. 4 and 5 best show housing 7 having solar panel 3 integrally formed thereon housing 7. Conductive wire 6 connects solar panel 3 to regulating circuit 5. Regulating circuit 5 is electrically connected to cord 8. Cord 8 has primary end 12 connected to a portion of regulating circuit 5 and secondary end 13 is adapted to connect to port 9 of wireless device 1. FIG. 3 shows wireless device 1 with housing 7 having cord 8 and solar panel 3.

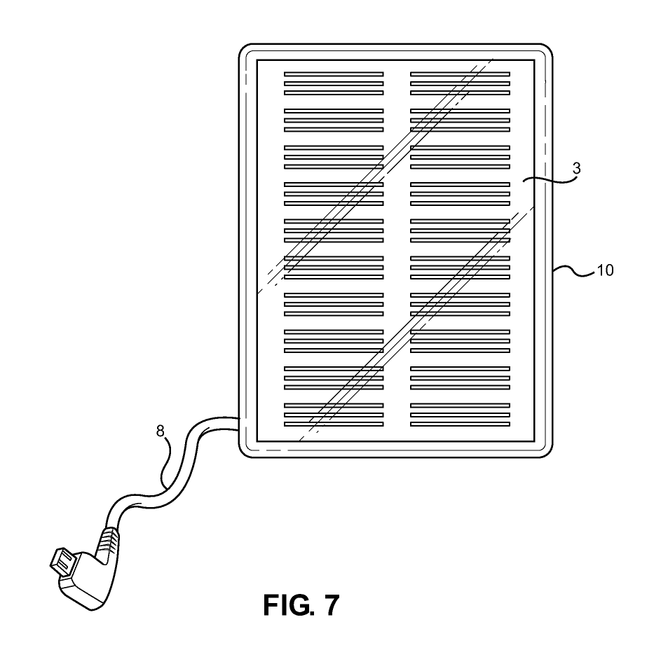

FIGS. 6 and 7 illustrate housing 10 connected to solar panel 3. Housing 10 has cord 8. FIG. 6 best depicts conductive wire 6 connecting solar panel 3 to regulating circuit 5. Regulating circuit 5 is electrically connected to cord 8. Cord 8 has primary end 12 connected to a portion of regulating circuit 5 and secondary end 13 adapted to connect to port 9 of wireless device 1. Attaching element 11 is connected to a surface of housing 10. Housing 10 is configured to connect to wireless device 1.

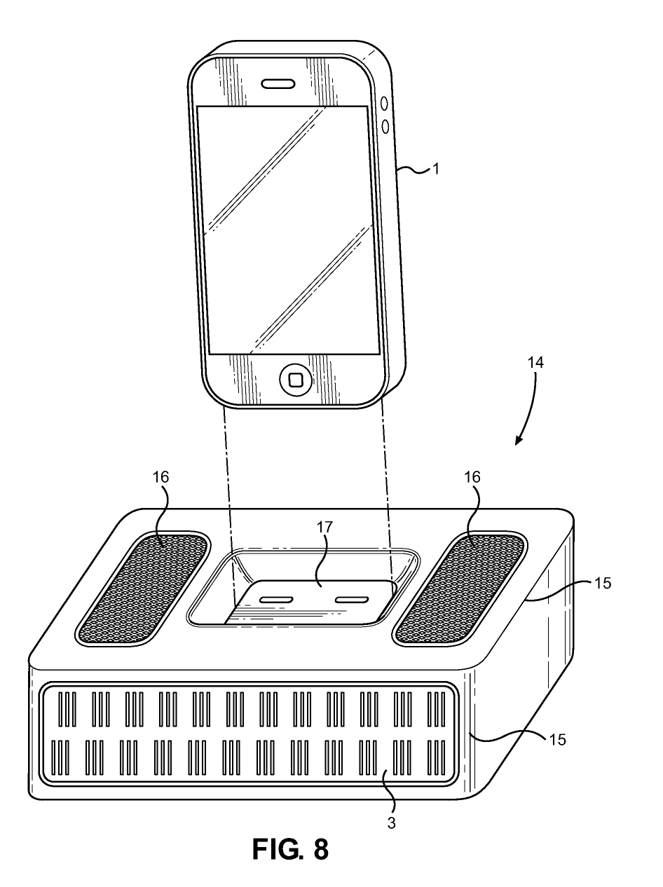

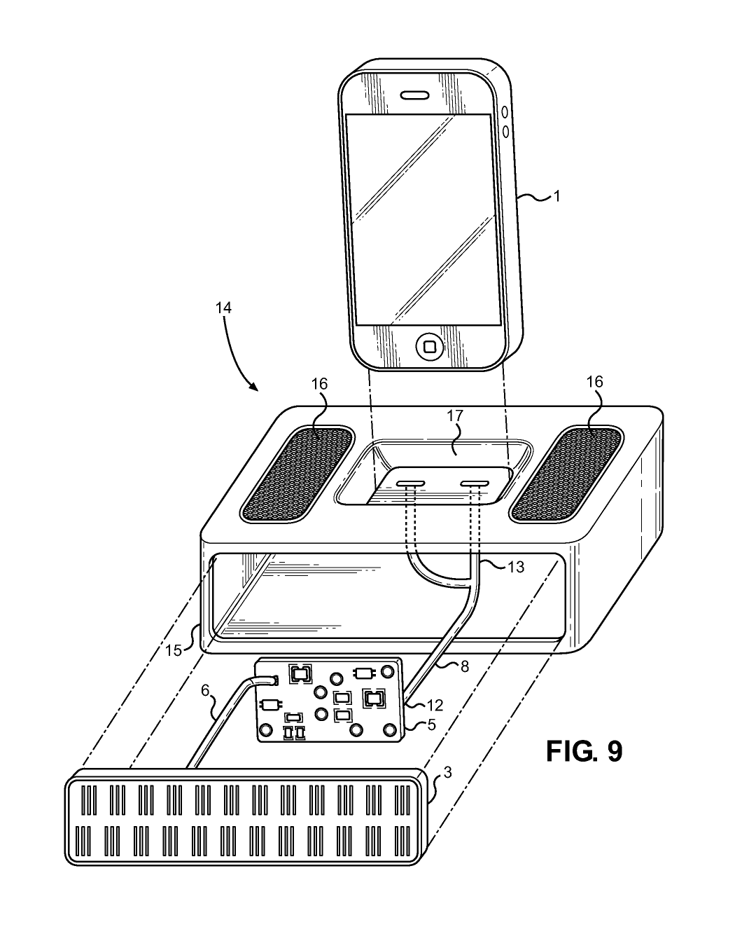

In an alternate embodiment, FIGS. 8 and 9 depict electrical charging dock 14 configured to receive wireless device 1. Supporting structure 15 has solar panel 3 integrally formed within supporting structure 15. Receiving structure 17 is configured to receive wireless device 1. Charging dock 14 can have at least one speaker 16 located on a surface thereon charging dock 14.

FIG. 9 has conductive wire 6 in electrical communication with solar panel 3. Solar panel 3 generates an electrical current to regulating circuit 5. Although not a preferred embodiment, it is within the scope of this invention for regulating circuit 5 to be in electrical communication with electrical conductor 8 having primary end 12 in electrical communication with regulating circuit 5. Electrical conductor 8 has secondary end 13 in electrical communication with wireless device 1.

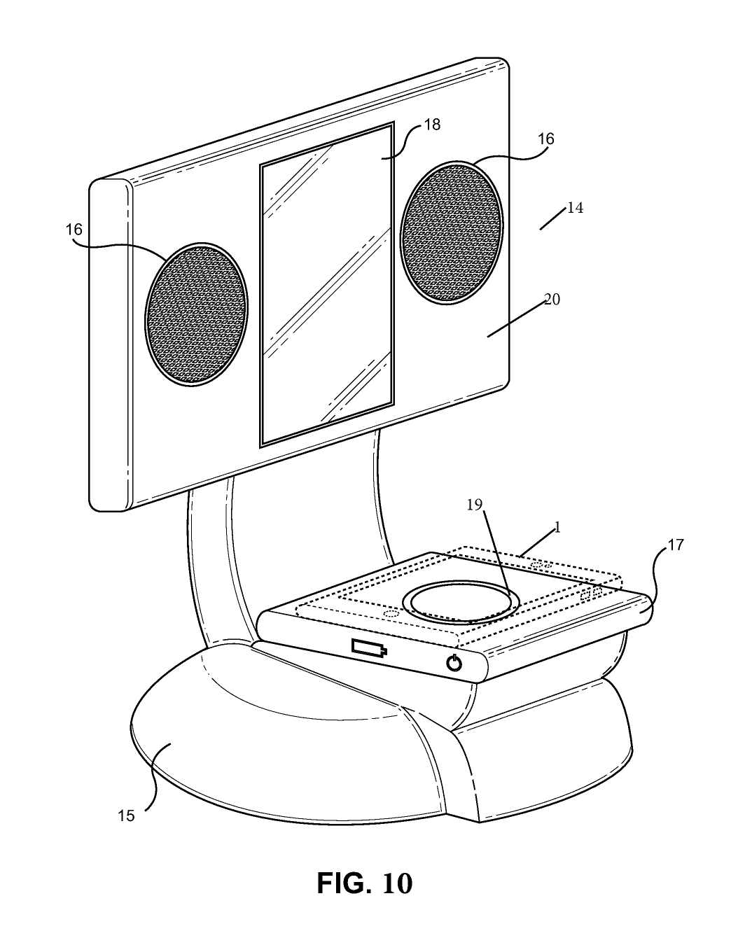

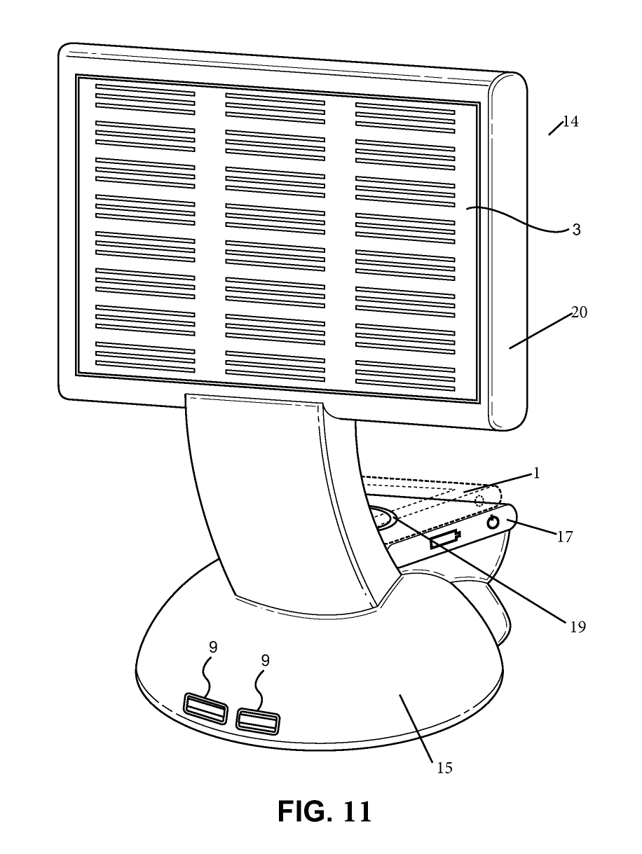

FIGS. 10 and 11 depict a preferred embodiment of electrical charging dock 14 configured to receive wireless device 1. Charging dock housing 20 has solar panel 3 integrally formed within charging dock housing 20. Charging dock housing 20 is adapted to hingedly pivot (not shown) from supporting structure 15 to fold over receiving structure 17 to a closed configuration (not shown) of approximately 0 degrees. Charging dock housing 20 is adapted to hingedly pivot (not shown) from supporting structure 15 to an open configuration (FIGS. 10-11) of approximately 90 degrees. Charging dock housing 20 is adapted to hingedly pivot (not shown) from an angle of 0 degrees to 180 degrees. Receiving structure 17 is configured to receive wireless device 1. Charging dock 14 can have at least one speaker 16 located on a surface thereon charging dock 14. Inductive charging primary coil 19 is located on receiving structure 17. Charging dock 14 has display screen 18 and opening 9 (FIG. 11). Opening 9 includes, but is not limited to, a UBS port.

It will thus be seen that the objects set forth above, and those made apparent from the foregoing description, are efficiently attained. Since certain changes may be made in the above construction without departing from the scope of the invention, it is intended that all matters contained in the foregoing description or shown in the accompanying drawings shall be interpreted as illustrative and not in a limiting sense.

It is also to be understood that the following claims are intended to cover all of the generic and specific features of the invention herein described, and all statements of the scope of the invention that, as a matter of language, might be said to fall therebetween.

Now that the invention has been described,

1-4. (canceled)

5. A housing encasing a wireless device in bidirectional communication with a communication system, comprising:
said housing comprising a compartment comprising a first wall located opposite a second wall, whereby, said first wall having an opening configured to enable installation of said wireless device into said compartment, said compartment comprising a compartment recess configured to retain said wireless device, said compartment comprising a retaining lip bordering said opening, whereby, said retaining lip is configured to overlap the entire perimeter of a front face of said wireless device;
said housing having a thermal radiant barrier, said thermal radiant barrier configured to deter thermal radiation from a light source, thereby, protecting said wireless device and electronics in said wireless device;
said housing having a solar panel integrally formed within a portion of said second wall of said housing;
an output circuit, said output circuit in electrical connection with said solar panel and generating an electrical current to a regulating circuit; and,
said regulating circuit in electrical connection with at least one electrical conductor, said at least one electrical conductor having a first end in electrical connection with said regulating circuit, said at least one electrical conductor having a second end adapted to be in electrical connection with a connector of said wireless device.

6. A housing connected to a wireless device in bidirectional communication with a communication system, comprising:
said housing connected to a solar panel;
an output circuit, said output circuit in electrical connection with said solar panel and generating an electrical current to a regulating circuit;
said regulating circuit in electrical connection with at least one electrical conductor, said at least one electrical conductor having a first end in electrical connection with a portion of said regulating circuit, said at least one electrical conductor having a second end in electrical connection with a connector of said wireless device; and,
a detachable attaching element, said detachable attaching element having a first surface located opposite a second surface, said first surface of said detachable attaching element configured to connect to a surface of said housing located opposite said solar panel, said second surface of said detachable attaching element configured to connect to a surface of said wireless device, said detachable attaching element configured to be located between said housing and said wireless device, thereby securing said housing to said wireless device.

7. The housing of claim 6, wherein said housing having at least one barrier element connected thereto.

8. The housing of claim 6, wherein said housing having a thermal radiant barrier.

9-12. (canceled)

13. A housing encasing a memory device having an electronic display, comprising:
said housing comprising a compartment comprising a first wall located opposite a second wall, whereby, said first wall having an opening configured to enable installation of said memory device into said compartment, said compartment comprising a compartment recess configured to retain said memory device, said compartment comprising a retaining lip bordering said opening, whereby, said retaining lip is configured to overlap the entire perimeter of a front face of said memory device;
said housing having a thermal radiant barrier, said thermal radiant barrier configured to deter thermal radiation from a light source, thereby, protecting said memory device and electronics in said memory device;
said housing having a solar panel integrally formed within a portion of said second wall of said housing;
an output circuit, said output circuit in electrical connection with said solar panel and generating an electrical current to a regulating circuit; and,
said regulating circuit in electrical connection with at least one electrical conductor, said at least one electrical conductor having a first end in electrical connection with said regulating circuit, said at least one electrical conductor having a second end in electrical connection with a connector of said memory device.

14-17. (canceled)

18. The housing of claim 5, wherein said housing having at least one barrier element connected thereto.

19. The housing of claim 5, wherein said solar panel having at least one barrier element connected thereto.

20. The housing of claim 5, wherein said wireless device having at least one barrier element connected thereto.

21. The housing of claim 13, wherein said housing having at least one barrier element connected thereto.

22. The housing of claim 13, wherein said solar panel having at least one barrier element connected thereto.

23. The housing of claim 13, wherein said memory device having at least one barrier element connected thereto.

24. A wireless device in bidirectional communication with a communication system, comprising:
a housing, said housing having a solar panel integrally formed within said housing, said housing adapted to connect to a battery of said wireless device;
an output circuit, said output circuit in electrical connection with said solar panel generating an electrical current to a regulating circuit;
said regulating circuit in electrical connection with said battery when said housing covers said battery; and,
said battery in electrical connection with said wireless device.

25. A memory device having an electronic display, comprising:
a housing, said housing having a solar panel integrally formed within said housing, said housing configured to be received by a portion of said memory device, whereby, said housing is configured to overlay said battery of said memory device, whereby, said housing is configured to be in direct connection with said battery of said memory device;
an output circuit, said output circuit in electrical connection with said solar panel and generating an electrical current to a regulating circuit;
said regulating circuit in electrical connection with a battery of said memory device when said housing covers said battery; and,
said battery in electrical connection with said memory device.

26. A housing connected to a memory device having an electronic display, comprising:
said housing connected to a solar panel;
an output circuit, said output circuit in electrical connection with said solar panel and generating an electrical current to a regulating circuit;
said regulating circuit in electrical connection with at least one electrical conductor, said at least one electrical conductor having a first end in electrical connection with said regulating circuit, said at least one electrical conductor having a second end in electrical connection with a connector of said memory device; and,
a detachable attaching element, said detachable attaching element having a first surface located opposite a second surface, said first surface of said detachable attaching element configured to connect connected to a surface of said housing located opposite said solar panel, said second surface of said detachable attaching element configured to connect to a surface of said memory device, said detachable attaching element configured to be located between said housing and said memory device, thereby securing, whereby, said housing is configured to connect to said memory device.
